(19) United States
(12) Patent Application Publication
(10) Pub. No.: US 2025/0034708 A1
(43) Pub. Date: Jan. 30, 2025

(54) MULTI-SUBSTRATE PROCESSING SYSTEM

(71) Applicant: Applied Materials, Inc., Santa Clara, CA (US)

(72) Inventor: Ala MORADIAN, Sunnyvale, CA (US)

(21) Appl. No.: 18/630,325

(22) Filed: Apr. 9, 2024

Related U.S. Application Data
(60) Provisional application No. 63/516,273, filed on Jul. 28, 2023.

(51) Int. Cl. C23C 16/455; C23C 16/44; C23C 16/48; H01L 21/677

(52) U.S. Cl. CPC C23C 16/45561; C23C 16/4412; C23C 16/482; C23C 16/488; H01L 21/67706

(57) ABSTRACT

A processing tool is provided including an exhaust inlet; two or more process chambers surrounding the exhaust inlet, each process chamber including: a chamber body enclosing an interior volume, the chamber body including a plurality of sidewalls that include one or more outer walls and one or more inner walls; one or more substrate supports disposed in the interior volume; a plurality of lamps positioned over each substrate support; a window positioned between the plurality of lamps and the substrate support; and a gas inlet that is located closer to one of the one or more outer walls than the gas inlet is to each of the one or more inner walls.

### RELATED APPLICATIONS

This application claims benefit of and priority to U.S. Provisional Patent Application No. 63/516,273, filed Jul. 28, 2023, the entire contents of which are incorporated herein by reference.

### BACKGROUND

Embodiments of the present disclosure generally relate to equipment and methods for performing processes (e.g., depositions and other processes) on substrates (e.g., semiconductor substrates) with increased throughput.

### DESCRIPTION OF THE RELATED ART

Forming devices on substrates, such as semiconductor substrates, generally includes a series of processes (e.g., deposition, etching, cleaning processes, etc.) performed on the substrate. Many of these processes are performed in different process chambers. For example, a first layer may be deposited on a substrate in a first process chamber, and a second layer may be deposited on the substrate in a second process chamber. Substrates are removed from each process chamber and transferred to another process chamber for the next process. One or more robots are generally used to transfer substrates between different process chambers. For the manufacturing of some devices, the number of transfers between process chambers can be quite high (e.g., greater than 50). Each transfer is time consuming, lowers the throughput, and raises the cost of production. Furthermore, each of the different processes generally uses a different process chamber, which increases footprint of the processing system, which increases capital and operating costs of the system.

Accordingly, there is an ongoing need for improved methods and equipment for performing a set of processes on substrates with increased throughput and smaller footprint.

### SUMMARY

In one embodiment, a processing tool is provided including an exhaust inlet; two or more process chambers surrounding the exhaust inlet, each process chamber comprising: a chamber body enclosing an interior volume, the chamber body comprising a plurality of sidewalls that include one or more outer walls and one or more inner walls; one or more substrate supports disposed in the interior volume; a plurality of lamps positioned over each substrate support; a window positioned between the plurality of lamps and the substrate support; and a gas inlet that is located closer to one of the one or more outer walls than the gas inlet is to each of the one or more inner walls.

In another embodiment, a processing system is provided comprising: a processing tool comprising: an exhaust inlet; one or more outer walls and two or more inner walls, the one or more outer walls and the two or more inner walls disposed around two or more interior volumes that are each coupled to the exhaust inlet, wherein the two or more inner walls and the two or more interior volumes surround the exhaust inlet; and four or more substrate supports, each interior volume including at least one substrate support; and a transfer chamber coupled to the processing tool, the transfer chamber including a transfer robot that is configured to: simultaneously remove a plurality of substrates from the processing tool during a first time period, wherein the plurality of substrates are positioned in a first arrangement over the four or more substrate supports when the substrates are positioned on the transfer robot during the first time period, change a position of the substrates on the transfer robot; and simultaneously insert each of the substrates into the processing tool during a second time period, wherein the plurality of substrates are positioned in a second arrangement over the four or more substrate supports when the substrates are positioned on the transfer robot during the second time period, and each substrate is positioned over a different substrate support during the second time period relative to the first time period.

In another embodiment, a processing tool is provided comprising: an exhaust inlet; four or more process chambers surrounding the exhaust inlet, each process chamber comprising: a chamber body enclosing an interior volume, the chamber body comprising a plurality of sidewalls that include one or more outer walls and one or more inner walls; one or more substrate supports disposed in the interior volume, wherein the one or more inner walls of each process chamber form a barrier between the interior volume of the process chamber and the interior volume of another one of the four or more process chambers; a plurality of lamps positioned over each substrate support; and a window positioned between the plurality of lamps and the substrate support; a first internal port configured to open to form a passageway from the interior volume of a first process chamber of the four or more process chambers to the interior volume of a second process chamber of the four or more process chambers; and a second internal port configured to open to form a passageway from the interior volume of a third process chamber of the four or more process chambers to the interior volume of a fourth process chamber of the four or more process chambers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 shows a top schematic view of a processing system, according to one embodiment.

FIG. 2 is a process flow diagram of a method of performing processes on a plurality of substrates in the processing system of FIG. 1, according to one embodiment.

FIGS. 3A-3H show the processing system of FIG. 1 during different portions of the method of FIG. 2, according to one embodiment.

FIG. 4 is a cross-sectional view of the processing tool of FIG. 1 taken along section line 4 of FIG. 3A, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to processing systems and methods for performing processes (e.g., depositions and other processes) on substrates (e.g., semiconductor substrates) with increased throughput. The processing systems can include a robotic end effector that can simultaneously insert multiple substrates (e.g., four substrates) into a corresponding number of different process chambers. The process systems can further include one more or other components to change the position of the substrates on the robotic end effector, so that the substrates can then each be simultaneously positioned into a different process chamber relative to the process chamber in which each substrate was previously positioned, which allows a different process to be performed on each of the substrates. The processing systems can further include a shared exhaust line positioned between the different process chambers, for example in a central location, which can reduce the footprint of the processing system relative to other multi-substrate processing systems.

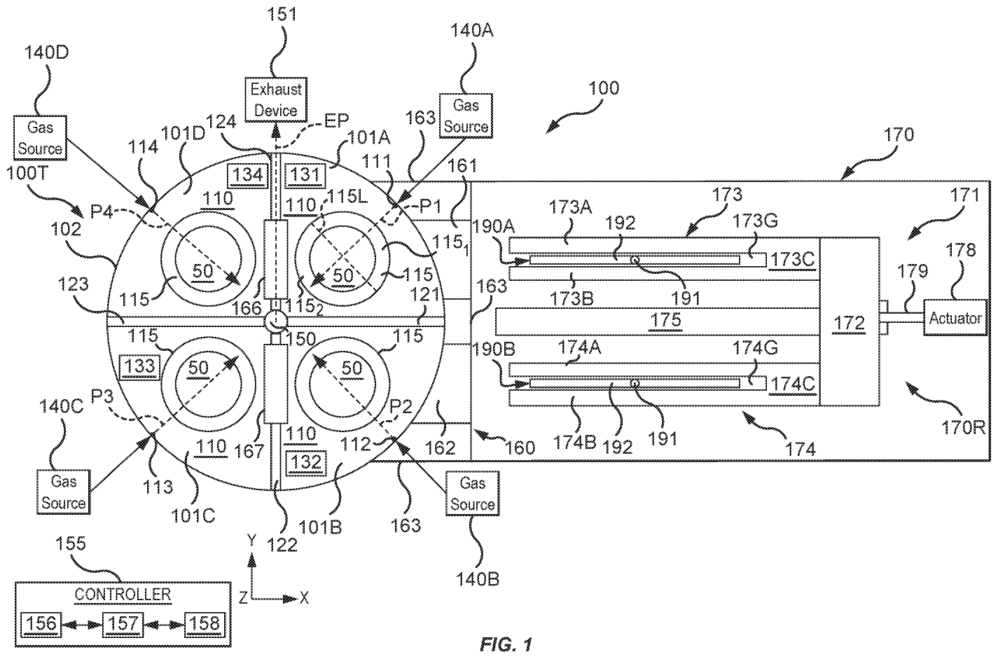

FIG. 1 shows a top schematic view of a processing system 100, according to one embodiment. The processing system 100 includes a processing tool 100T that includes a plurality of process chambers 101, a transfer chamber 170, and an external access device 160. The external access device 160 connects the process chambers 101 to the transfer chamber 170, so that substrates 50 can be inserted and removed from the process chambers 101. The processing system 100 further includes a plurality of gas sources 140, an exhaust device 151, and a controller 155 as described in further detail below.

The processing tool 100T includes four process chambers 101 that include a first process chamber 101A, a second process chamber 101B, a third process chamber 101C, and a fourth process chamber 101D. Each process chamber 101 includes an interior volume 110 and a substrate support 115 positioned in the interior volume 110. A substrate 50 is shown positioned on the substrate support 115 of each process chamber 101. The processing tool 100T includes an outer wall 102. In some embodiments, the outer wall 102 can have a circular profile as shown and can extend around the entire processing tool 100T. Other embodiments can include a plurality of outer walls having other profiles (e.g., rectangular) that form part of the exterior body of the processing tool 100T. The outer wall 102 can connect to a top and bottom (not shown) of the exterior body of the processing tool 100T.

The processing system 100 further includes a plurality of gas sources 140 configured to provide one or more gases to the interior volumes 110 of the different process chambers 101. In some embodiments, each of the process gas sources 140 can be configured to provide a plurality of different types of gases, such as process gases, cleaning gases, and purge gases. A first gas source 140A is connected to the interior volume 110 of the first process chamber 101A through a first gas inlet 111. A second gas source 140B is connected to the interior volume 110 of the second process chamber 101B through a second gas inlet 112. A third gas source 140C is connected to the interior volume 110 of the third process chamber 101C through a third gas inlet 113. A fourth gas source 140D is connected to the interior volume 110 of the fourth process chamber 101D through a fourth gas inlet 114. Each gas inlet 111-114 can be located closer to a portion of the outer wall 102 than to any portion of the barriers 121-124 that are described in further detail below. In some embodiments, each gas inlet 111-114 is part of a gas supply line that extends through a portion of the outer wall 102 that forms part of the chamber body for that process chamber 101.

The processing system 100 further includes an exhaust inlet 150 and an exhaust device 151, such as a vacuum pump. The exhaust inlet 150 is connected to the exhaust device 151, so that gas can be exhausted from the exhaust inlet 150 to the exhaust device 151 along an exhaust path EP.

The exhaust inlet 150 is further connected to the interior volume 110 of each process chamber 101. The exhaust inlet 150 can be positioned at a central location of the processing tool 100T. The process chambers 101 can surround the exhaust inlet 150. Gas from the first gas source 140A can (1) enter the interior volume 110 of the first process chamber 101A, (2) flow along a first gas flow path P1 over the substrate support 115 in the interior volume 110 of the first process chamber 101A, and (3) flow into to the exhaust inlet 150. Gas from the second gas source 140B can (1) enter the interior volume 110 of the second process chamber 101B, (2) flow along a second gas flow path P2 over the substrate support 115 in the interior volume 110 of the second process chamber 101B, and (3) flow into the exhaust inlet 150. Gas from the third gas source 140C can (1) enter the interior volume 110 of the third process chamber 101C, (2) flow along a third gas flow path P3 over the substrate support 115 in the interior volume 110 of the third process chamber 101C, and (3) flow into the exhaust inlet 150. Gas from the fourth gas source 140D can (1) enter the interior volume 110 of the fourth process chamber 101D, (2) flow along a fourth gas flow path P4 over the substrate support 115 in the interior volume 110 of the fourth process chamber 101D, and (3) flow into the exhaust inlet 150.

The gas from the gas sources 140 can be configured to flow across the interior volume 110 of each process chamber 101 and over the substrate 50 on the substrate support 115. The gas inlet 111-114 of each process chamber 101 can be described as being located on a first side of the substrate support 115, and the exhaust inlet 150 can be described as being located on an opposing side of the substrate support 115. For example, for the first process chamber 101A, a line 115L is shown bisecting the substrate support 115 into a first side 1151 and a second side 1152. The gas inlet 111 for the first process chamber 101A is located on the first side 1151 of the substrate support 115, and the exhaust inlet 150 is located on the opposing second side 1152 of the substrate support 115.

The processing system 100 further includes a plurality of barriers 121-124 that separate the interior volumes 110 of the process chambers 101 from each other. For example, in some embodiments, each barrier 121-124 can form a barrier between the interior volume 110 of a process chamber 101 and the interior volume 110 of one or more other process chambers 101. Keeping the interior volumes 110 of the process chambers 101 separate from each other can enable different processes to be performed in the different process chambers 101. The separate interior volumes 110 can also keep potential problems from one process chamber 101, such as particles, from entering the interior volume 110 of another process chamber 101. Each interior volume 110 is enclosed by the chamber body for that process chamber 101. The chamber body for each process chamber 101 includes two of the barriers 121-124, a portion of the outer wall 102, and a top and a bottom (not shown) of each process chamber 101. The barriers 121-124 can also be referred to as inner walls. The barriers 121-124 and the interior volumes 110 can surround the exhaust inlet 150. The barriers 121-124 and the outer wall 102 can collectively be referred to as a plurality of sidewalls that form part of the chamber body for each process chamber 101. In some embodiments, the barriers 121, 123 can be omitted, so that there would only be two interior volumes on either side of the barriers 122, 124. A same process can then be performed on the substrates on opposing sides of the barriers 122, 124, such as a deposition being performed on a first side of the barriers 122, 124, and a cleaning process being performed on the opposing side of the barriers 122, 124.

A first barrier 121 separates the interior volume 110 of the first process chamber 101A from the interior volume 110 of the second process chamber 101B. A second barrier 122 separates the interior volume 110 of the second process chamber 101B from the interior volume 110 of the third process chamber 101C. A third barrier 123 separates the interior volume 110 of the third process chamber 101C from the interior volume 110 of the fourth process chamber 101D. A fourth barrier 124 separates the interior volume 110 of the fourth process chamber 101D from the interior volume 110 of the first process chamber 101A.

The processing system 100 further includes the external access device 160 to enable substrates 50 to be transferred into and removed from the process chambers 101. The external access device 160 includes a first external port 161, a second external port 162, and a housing 163. The first external port 161 and the second external port 162 are supported by the housing 163. The first external port 161 is configured to open to allow a robotic end effector 171 of a transfer robot 170R in the transfer chamber 170 to access the interior volumes 110 of the first process chamber 101A and the fourth process chamber 101D. The second external port 162 is configured to open to allow the robotic end effector 171 of the transfer robot 170R to access the interior volumes 110 of the second process chamber 101B and the third process chamber 101C. In one embodiment, the first external port 161 and the second external port 162 are each slit valves that can open from a closed position to provide access to interior volumes 110 of the corresponding process chambers 101.

The processing system 100 further includes a first internal port 166 and a second internal port 167. Each internal port can be configured to open to form a passageway from the interior volume 110 of one process chamber 101 of the plurality of more process chambers 101 to the interior volume 110 of another process chamber 101 of the plurality of process chambers 101. The first internal port 166 can be configured to open to form a passageway to allow the robotic end effector 171 to extend through the interior volume 110 of the first process chamber 101A and into the interior volume 110 of the fourth process chamber 101D. The second internal port 167 can be configured to open to form a passageway to allow the robotic end effector 171 to extend through the interior volume 110 of the second process chamber 101B and into the interior volume 110 of the third process chamber 101C. In one embodiment, the first internal port 166 and the second internal port 167 are each slit valves. The first internal port 166 can be attached (e.g., mounted) to the fourth barrier 124. The second internal port 167 can be attached (e.g., mounted) to the second barrier 122.

The transfer chamber 170 includes the transfer robot 170R. The transfer robot 170R includes a robotic end effector 171, a guide 175, an actuator 178, and a shaft 179 coupled between the actuator 178 and the robotic end effector 171. The actuator 178 can extend and retract the shaft 179 to move the robotic end effector 171 in the X-direction, so that the end effector 171 can be inserted into the process chambers 101 and removed from the process chambers 101 for exchange of substrates 50 between the transfer chamber 170 and the process chambers 101.

The end effector 171 includes a base 172, a first blade 173, and a second blade 174. The first blade 173 and the second blade 174 are each connected to the base 172.

The first blade 173 includes a first arm 173A, a second arm 173B, and a connecting portion 173C that is coupled to each arm 173A, 173B. The connecting portion 173C connects the arms 173A, 173B with the base 172. The first arm 173A is spaced apart from the second arm 173B by a gap 173G. The first blade 173 is aligned with the first external port 161, so that the first blade 173 can enter the interior volume 110 of the first process chamber 101A when the end effector 171 is moved in the X-direction towards the processing tool 100T. The first blade 173 is also aligned with the first internal port 166, so that the first blade 173 is also configured to enter the interior volume 110 of the fourth process chamber 101D when the end effector 171 is moved in the X-direction through the first process chamber 101A and into the interior volume 110 of the fourth process chamber 101D.

Similarly, the second blade 174 includes a first arm 174A, a second arm 174B, and a connecting portion 174C that is coupled to each arm 174A, 174B. The connecting portion 174C connects the arms 174A, 174B with the base 172. The first arm 174A is spaced apart from the second arm 174B by a gap 174G. The second blade 174 is aligned with the second external port 162, so that the second blade 174 can enter the interior volume 110 of the second process chamber 101B when the end effector 171 is moved in the X-direction towards the processing tool 100T. The second blade 174 is also aligned with the second internal port 167, so that the second blade 174 is also configured to enter the interior volume 110 of the third process chamber 101C when the end effector 171 is moved in the X-direction through the second process chamber 101B and into the interior volume 110 of the third process chamber 101C.

The transfer robot 170R further includes a first rotatable support 190A and a second rotatable support 190B. The rotatable supports 190A, 190B are used to change the position of the substrates 50 on the end effector 171, so that each of the substrates 50 can be positioned in a different process chamber 101 as described in further detail below. Each rotatable support 190A, 190B includes a shaft 191 and a support 192. The shaft 191 can be configured to (1) raise and lower the corresponding support 192, and (2) rotate the corresponding support 192, for example by 180 degrees. Each shaft 191 can be coupled to one or more actuators (not shown) to assist in the raising, lowering, and rotation of the corresponding supports 192.

The first rotatable support 190A is positioned so that the shaft 191 and the support 192 can extend vertically through the gap 173G of the first blade 173, so that one or more substrates 50 (e.g., two substrates 50) can be lifted from the first blade 173 or lowered onto the first blade 173. Similarly, the second rotatable support 190B is positioned so that the shaft 191 and the support 192 can extend vertically through the gap 174G of the second blade 174, so that one or more substrates 50 (e.g., two substrates can be lifted from the second blade 174 or lowered onto the second blade 174.

The transfer robot 170R is just one example of how substrates 50 can be rearranged to enable the substrates 50 to be quickly positioned in a different process chamber 101 when the transfer robot 170R reinserts the substrates 50 into the processing tool 100T. In another embodiment, the rotatable supports 190A, 190B can be omitted, (2) the blades 173, 174 can move in the X-direction relative to the base 172, and (3) the base 172 can rotate 180 degrees, so that the arrangement of the four substrates 50 can be changed without removing the substrates from the blades 173, 174. The substrates 50 can then be reinserted into the four different process chambers 101 simultaneously in the new arrangement, so that each substrate 50 can be processed in a different process chamber 101, for example so that a different process can be performed on each of the substrates 50.

Furthermore, although the transfer robot 170R is configured to support and position four substrates 50 into the process chambers 101 simultaneously, other transfer robots can be used. For example, in some embodiments a transfer robot that is configured to support and transport two substrates 50 simultaneously can be used. This transfer robot can be configured to enter the interior volumes 110 of two of the process chambers 101 simultaneously, for example when one of the internal ports 166, 167 is opened. In other embodiments, a transfer robot that is configured to handle a single substrate 50 can be used. In some of these embodiments, the transfer chamber that includes the transfer robot can include a rack or other component to allow the transfer robot to position the substrates in different process chambers 101 of the processing tool 100T. The transfer robot that is configured to support a single substrate 50 can be configured to enter any of the process chambers 101. For example, the transfer robot configured to support a single substrate 50 can enter the interior volume 110 of the fourth process chamber 101D through the first internal port 166.

The processing system 100 also includes the controller 155 for controlling processes performed by the processing system 100. The controller 155 can be any type of controller used in an industrial setting, such as a programmable logic controller (PLC). The controller 155 includes a processor 157, a memory 156, and input/output (I/O) circuits 158. The controller 155 can further include one or more of the following components (not shown), such as one or more power supplies, clocks, communication components (e.g., network interface card), and user interfaces typically found in controllers for semiconductor equipment.

The memory 156 can include non-transitory memory. The non-transitory memory can be used to store the programs and settings described below. The memory 156 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 157 is configured to execute various programs stored in the memory 156, such as processes for positioning the substrates 50 into the different process chambers 101 as well as processes (e.g., depositions) that can be performed in the different process chambers 101. During execution of these programs, the controller 155 can communicate to I/O devices through the I/O circuits 158. For example, during execution of these programs and communication through the I/O circuits 158, the controller 155 can control outputs, such as the position of valves to provide gases to the interior volumes 110 of the different process chambers 101. The memory 156 can further include various operational settings used to control the processing system 100. For example, the settings can include process conditions, such as temperature setpoints during different processes performed in the different process chambers 101 as well as timers for how long to perform the different processes in the different process chambers 101.

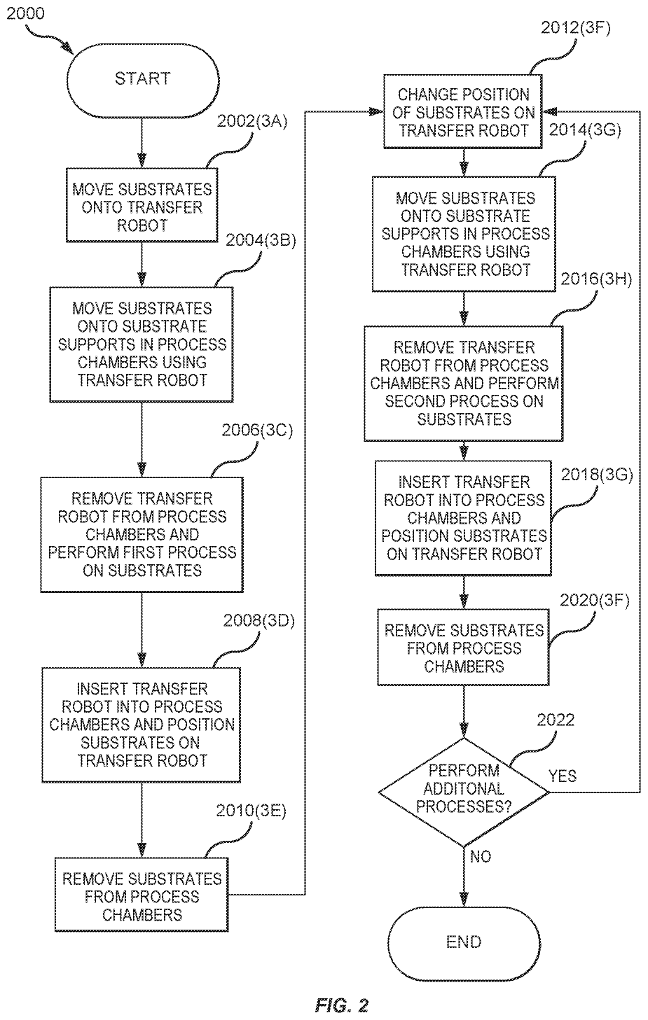

FIG. 2 is a process flow diagram of a method 2000 of performing processes on a plurality of substrates 50 in the processing system 100 of FIG. 1, according to one embodiment. The method 2000 is described in reference to FIGS. 1, 2, and 3A-3H.

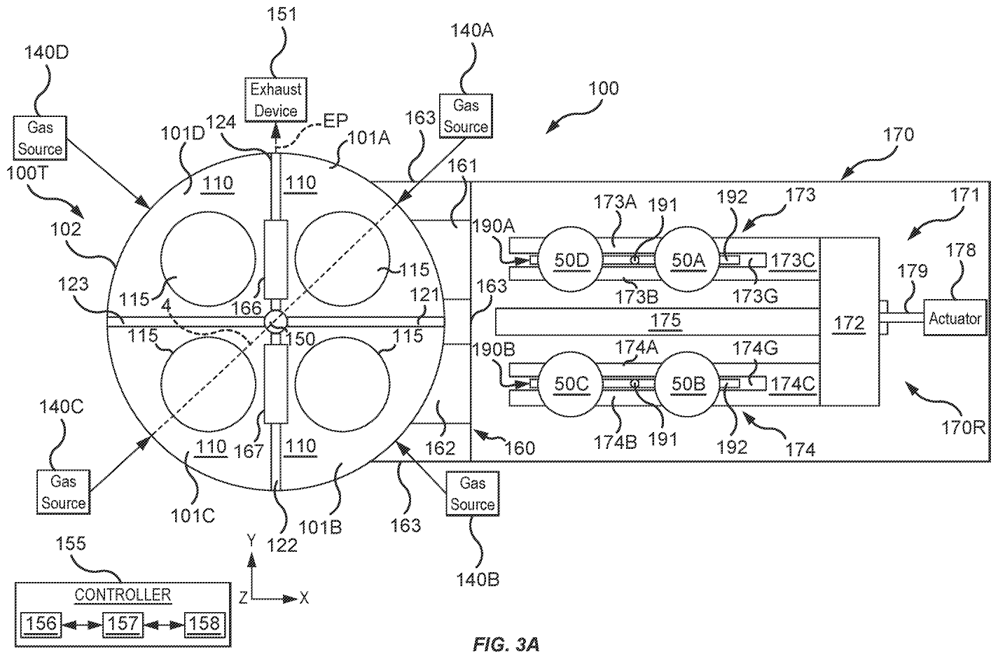

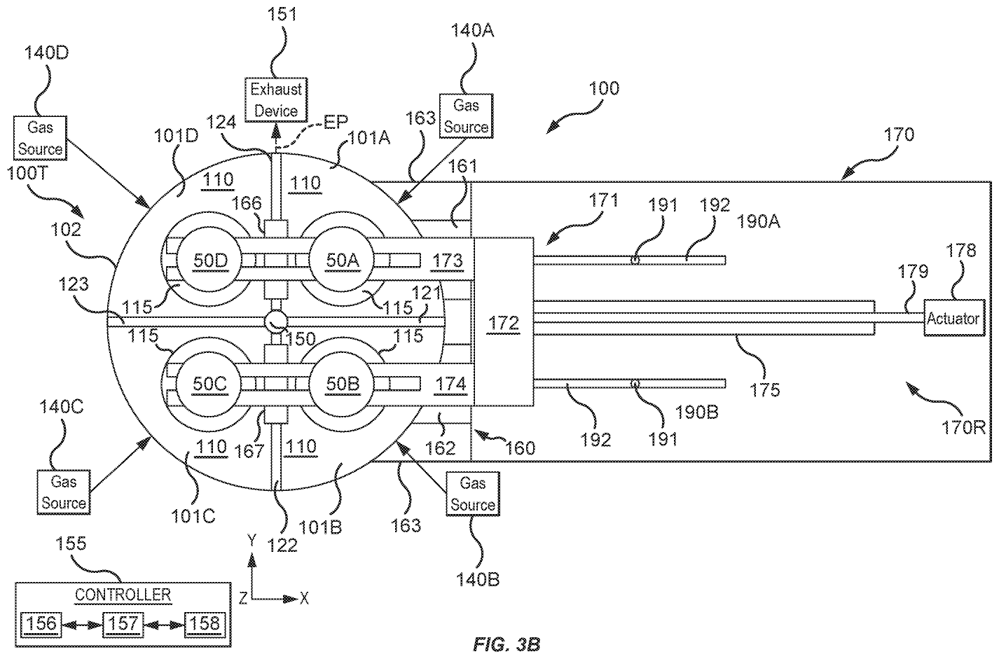

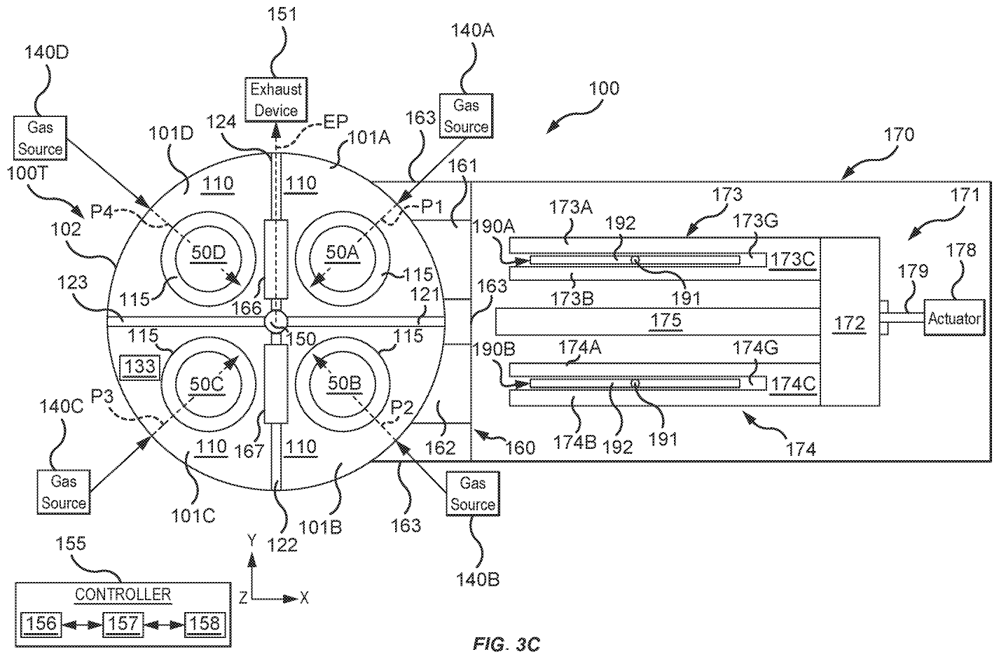

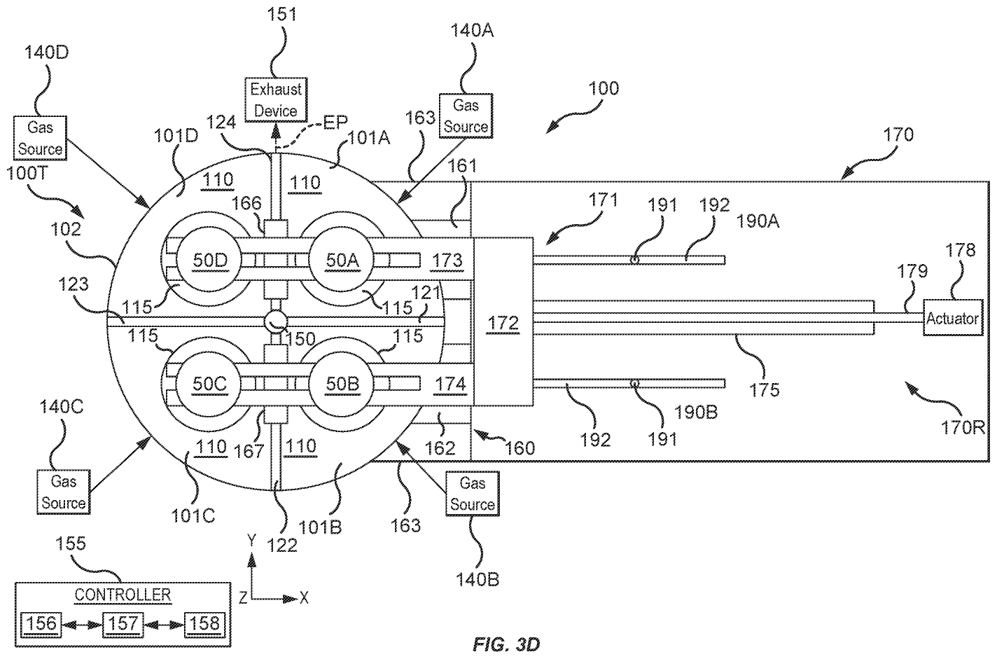

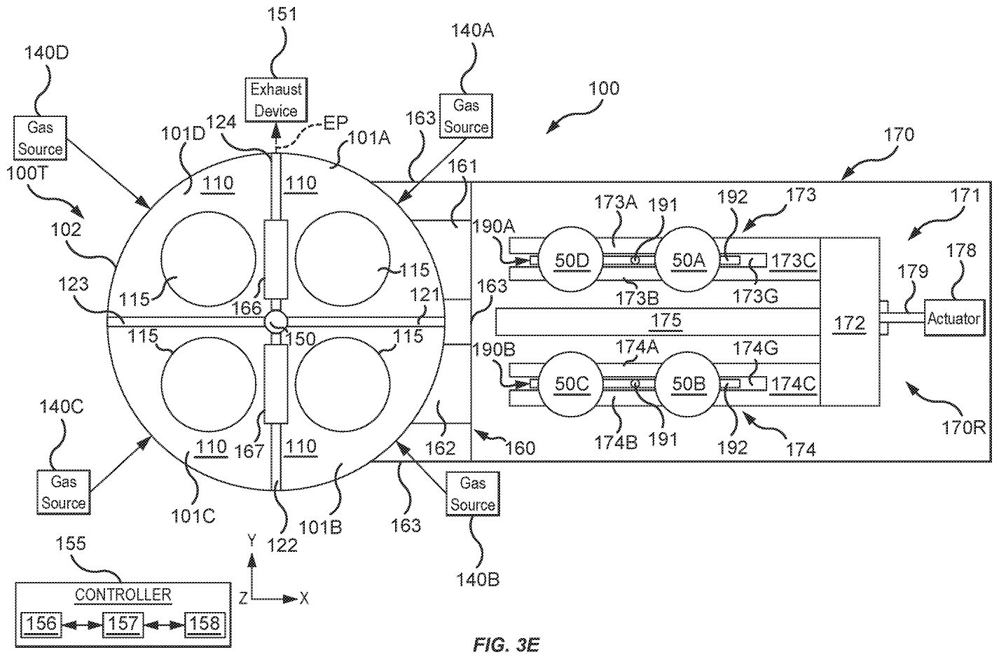

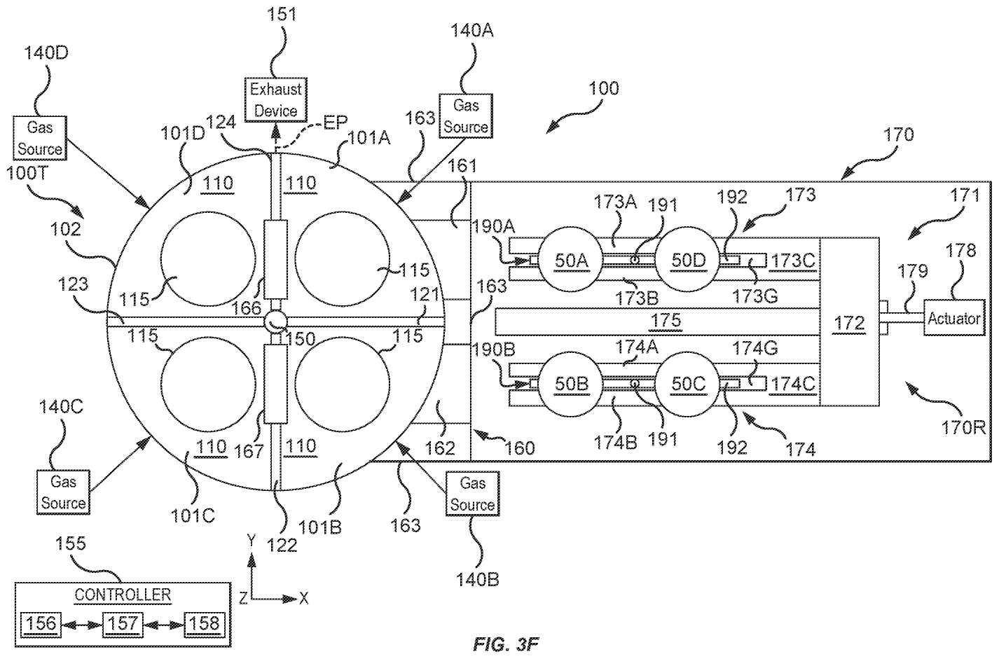

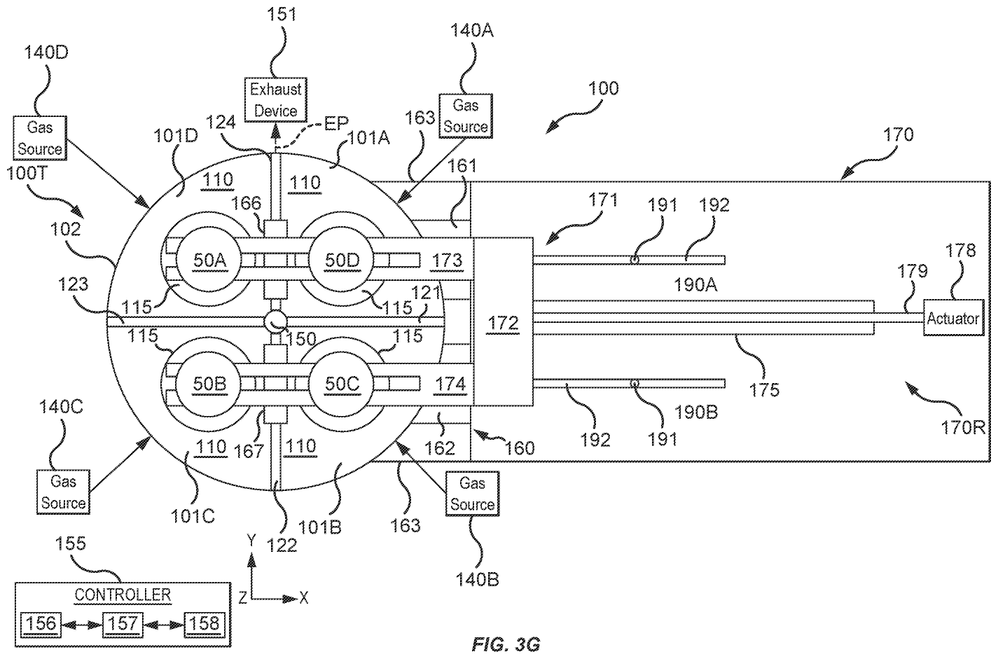

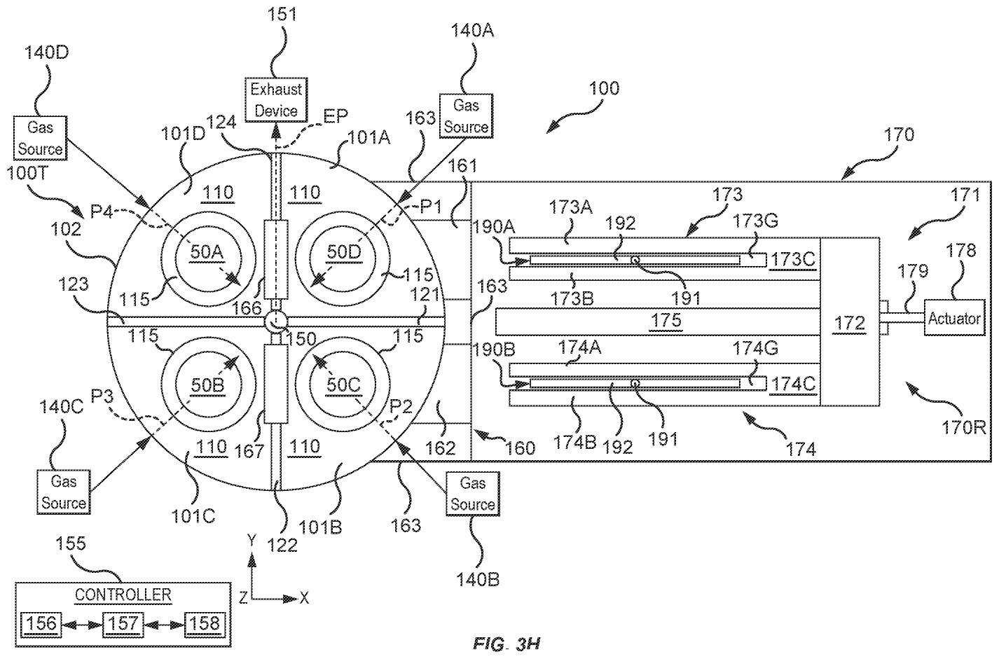

The method 2000 begins at block 2002. At block 2002, four substrates 50A, 50B, 50C, and 50D (also referred to as a plurality of substrates) are positioned on the end effector 171 of the transfer robot 170R as shown in FIG. 3A. In one embodiment, an external robot housed in another chamber (not shown) can be used to position the substrates 50 on the end effector 171 of the transfer robot 170R.

At block 2004, with reference to FIG. 3B, the substrates 50 are moved into the process chambers 101 by the transfer robot 170R, and the substrates 50 are positioned onto the substrate supports 115 in each of the process chambers 101. The substrates 50 can be moved into the process chambers 101 simultaneously by the transfer robot 170R. The first substrate 50A is positioned on the substrate support 115 in the first process chamber 101A. The second substrate 50B is positioned on the substrate support 115 in the second process chamber 101B. The third substrate 50C is positioned on the substrate support 115 in the third process chamber 101C. The fourth substrate 50D is positioned on the substrate support 115 in the fourth process chamber 101D. Each process chamber 101 can include lift pins (not shown) that can extend above the corresponding substrate support 115 to lift the substrates 50 above the end effector 171 of the transfer robot 170R, so that transfer robot 170R can be removed from the process chambers 101. The external ports 161, 162 and the internal ports 166, 167 can be opened during block 2004 to allow for the movement of the transfer robot 170R into each of the process chambers 101.

At block 2006, with reference to FIG. 3C, the transfer robot 170R is removed from the process chambers 101, and a first process is performed on each of the substrates 50 in the corresponding process chambers 101. Each of the external ports 161, 162 and the internal ports 166, 167 can be closed after removal of the transfer robot 170R from the process chambers 101 and before the starting of the first process on each of the substrates 50, so that each of the interior volumes 110 is not exposed to another environment.

In some embodiments, a different process can be performed in each process chamber 101 during block 2006. In some of these embodiments, each process chamber 101 can include at least one component that is used for performing a particular process. FIG. 1 shows that each process chamber 101 can include a unique component 131-134 that is not included in the other process chambers 101. The other process chambers 101 can be unable to perform a particular process without this other component. For example, in one embodiment, component 131 included in process chamber 101A can be equipment for generating a capacitively coupled plasma, and the other process chambers 101B-101D can lack components for generating a capacitively coupled plasma. Components 132-134 in process chambers 110B-101D can also be components that are unique to the process chamber 101 in which the component is included, such as specialized reflectors for performing an epitaxial deposition, so that process chamber 101 can also perform a process that the other process chambers 101 are unable to perform.

In some embodiments, a first same process can be performed on two of the substrates 50 and a second same process can be performed on the other two substrates 50. For example, in one embodiment a first deposition, such as a deposition of silicon oxide, can be performed in process chambers 101A, 101B, and a second deposition, such as a deposition of silicon nitride, can be performed in the process chambers 101C, 101D. In another embodiment, a preclean process can be performed in the process chambers 101A, 101B, and a same deposition process (e.g., deposition of silicon oxide) can be performed in process chambers 101C, 101D.

At block 2008, with reference to FIG. 3D, the transfer robot 170R is inserted into the process chambers 101 and the substrates 50 are positioned on the blades 173, 174 of the end effector 171. Lift pins (not shown) can be used to lift each substrate 50 above the blades 173, 174 of the end effector 171 before the transfer robot 170R is inserted into each of the process chambers 101. The lift pins can then lower the substrates 50 onto the corresponding blades 173, 174 as shown in FIG. 3D to position the substrates 50 in a first arrangement on the end effector 171 during a first time period. The substrates 50 are also moved into the processing tool 100T in the first arrangement as shown in FIG. 3B and processed in the first arrangement as shown in FIG. 3C.

At block 2010, with reference to FIG. 3E, the substrates 50 are removed from the process chambers 101 by the transfer robot 170R and are positioned in the transfer chamber 170. The substrates 50 can be removed from the process chambers 101 simultaneously by the transfer robot 170R. The ports 161, 162, 166, 167 are opened during blocks 2008, 2010 to allow the movement of the end effector 171 of the transfer robot 170R into and out of the process chambers 101.

At block 2012, with reference to FIG. 3F, the rotatable supports 190A, 190B of the transfer robot 170R change the position of the substrates 50 on the corresponding blades 173, 174 of the end effector 171 of the transfer robot 170R from a first set of positions (first arrangement as shown in FIG. 3E) to a second set of positions (second arrangement as shown in FIG. 3F) during a second time period. For example, before the change in positions (see FIG. 3E), the substrates 50C, 50D are positioned between the substrates 50A, 50B and the processing tool 170T while after the change in positions (see FIG. 3F), the substrates 50A, 50B are positioned between the processing tool 100T and the substrates 50C, 50D. This change in positions moves the substrates 50A, 50B closer to process chambers 101 and moves the substrates 50C, 50D further from the process chambers 101. The change in positions enables the transfer robot 170R to easily position the substrates 50 in a different process chamber 101 relative to the position of that substrate 50 during blocks 2004-2008, so that a different process can be performed on each substrate 50 relative to the process performed at block 2006 (see FIG. 3C).

The rotatable supports 190A, 190B can change the positions of the substrates 50 by (1) raising the supports 192 to lift the substrates 50 above the corresponding blades 173, 174, (2) rotating the shaft 191 and the supports 192 by 180 degrees, and (3) lowering the supports 192 to lower the substrates 50 back onto the corresponding blade 173, 174. The rotatable supports 190A, 190B are just one example of equipment that can be used to change the positions of the substrates 50 on the corresponding blades 173, 174. In another embodiment (not shown), the blades 173, 174 can move in the X-direction relative to the base 172, and the blades can each individually rotate by 180 degrees so that the position of the substrates 50 can be changed in a similar manner to achieve the position shown in FIG. 3F without removing the substrates 50 from the corresponding blades 173, 174.

At block 2014, with reference to FIG. 3G, the substrates 50 in the second arrangement are moved into the process chambers 101 by the transfer robot 170R during the second time period, and the substrates are positioned onto the substrate supports 115 in each of the process chambers 101. The substrates 50 can be moved into the process chambers 101 simultaneously by the transfer robot 170R.

Each substrate 50 is positioned over a different substrate support 115 during the second time period in the second arrangement (FIG. 3G) relative to the first time period in the first arrangement (FIG. 3D). The fourth substrate 50D is positioned on the substrate support 115 in the first process chamber 101A. The third substrate 50C is positioned on the substrate support 115 in the second process chamber 101B. The second substrate 50B is positioned on the substrate support 115 in the third process chamber 101C. The first substrate 50A is positioned on the substrate support 115 in the fourth process chamber 101D. The lift pins (not shown) can be used to lift the corresponding substrates 50 above the end effector 171 of the transfer robot 170R, so that transfer robot 170R can be removed from the process chambers 101. The lift pins then lower the substrates 50 onto the respective substrate supports 115. The ports 161, 162, 166, 167 are opened during blocks 2014 to allow the movement of the end effector 171 of the transfer robot 170R into and out of the process chambers 101.

At block 2016, with reference to FIG. 3H, the transfer robot 170R is removed from the process chambers 101, and a second process is performed on each of the substrates 50 in the corresponding process chambers 101. Each of the external ports 161, 162 and the internal ports 166, 167 can be closed after removal of the transfer robot 170R from the process chambers 101 and before the starting of the second process on each of the substrates 50.

The second process performed on each substrate 50 is different than the first process performed on that substrate 50 during block 2006. For example, in one embodiment, a cleaning process is performed on substrates 50C, 50D in corresponding process chambers 101C, 101D during block 2006, and a deposition is performed on substrates 50A, 50B in corresponding process chambers 101A, 101B during block 2006 while at block 2016, the same cleaning process is performed on substrates 50A, 50B in corresponding process chambers 101C, 101D and the same deposition is performed on substrates 50D, 50D in corresponding process chambers 101A, 101B. In another embodiment, a first type of layer (e.g., silicon nitride) is deposited on substrates 50A, 50B in corresponding process chambers 101A, 101B during block 2006 and a second type of layer (e.g., silicon oxide) is deposited on substrates 50C, 50D in corresponding process chambers 101C, 101D during block 2006 while at block 2016, the second type of layer (i.e., silicon oxide) is deposited on substrates 50A, 50B in corresponding process chambers 101C, 101D, and the first type of layer (i.e., silicon nitride) is deposited on the substrates 50C, 50D in corresponding process chambers 101A, 101B.

In yet another embodiment, each process chamber 101 can be used to perform a different process, and the transfer robot 170R can be configured to insert each different substrate 50 into each different process chamber 101, so that four different processes can performed on each substrate 50 in the processing tool 100T. For example, in one of these embodiments, the end effector 171 can rotate by 180 degrees and the individual blades 173, 174 can (1) move in the X-direction relative to the base 172 and (2) rotate, for example by 180 degrees, so that each substrate 50 can be moved to a position to be inserted into each of the different four process chambers 101.

At block 2018, with reference to FIG. 3G, the transfer robot 170R is inserted into each of the process chambers 101 and the substrates 50 are positioned on the blades 173, 174 of the end effector 171. Lift pins (not shown) can be used to lift each substrate 50 above the blades 173, 174 of the end effector 171 before the transfer robot 170R is inserted into each of the process chambers 101. The lift pins then lower the substrates 50 onto the corresponding blades 173, 174 as shown in FIG. 3G.

At block 2020, with reference to FIG. 3F, the substrates 50 are removed from the process chambers 101 by the transfer robot 170R and are positioned in the transfer chamber 170. The substrates 50 can be removed from the process chambers 101 simultaneously by the transfer robot 170R. The ports 161, 162, 166, 167 are opened during blocks 2008, 2010 to allow the movement of the end effector 171 of the transfer robot 170R into and out of the process chambers 101.

At block 2022, a decision is made on whether to perform additional processes on the substrates 50. If additional processes are not to be performed, then the method 2000 can end and the substrates 50 can be removed from the transfer chamber 170, for example by another robot (not shown). If additional processes are to be performed on the substrates 50, then the method 2000 can return to block 2012, so that the position of the substrates 50 on the blades 173, 174 of the end effector 171 can be changed again by the rotatable supports 190A, 190B, which enables the transfer robot 170R to position the substrates 50 into different process chambers 101 relative to the position of substrates during the last execution of block 2014.

In one embodiment, the rotatable supports 190A, 190B are used to raise the substrates 50, rotate the substrates 50, and lower the substrates 50 back onto the end effectors, so that the substrates 50 return to the position on the blades 173, 174 originally shown in FIG. 3A. After the substrates 50 are repositioned during the second execution of block 2012, then blocks 2014-2020 can be performed again. After block 2020 is performed for a second time, block 2022 can be executed again, and blocks 2012-2022 can then be executed any number of times, so that additional processes can be performed on the substrates 50 with the substrate 50 being positioned in a different process chamber during each execution of block 2016 relative to the most recent execution of block 2016.

The processing system 100 described herein enables the position of the substrates 50 to be quickly rearranged, so that the substrates 50 can be quickly positioned in a different process chamber, which allows a different process to be performed on each substrate 50 relative to the most recent process performed on the substrate 50. This feature of quickly rearranging the substrates 50 can be especially useful for devices that are formed using alternating depositions of layers where the alternating layers may be deposited more than ten times or even more than 100 times on each substrate.

Although the processing tool 100T described above includes four processing chambers 101A-101D, other embodiments can include two or more process chambers (e.g., two process chambers, for example when the first and third barriers 121, 123 are omitted) or more than four process chambers (e.g., six process chambers). These other embodiments can include an exhaust inlet 150 in a central location like the exhaust inlet 150 described above. Furthermore, in some embodiments, the process chambers can include two or more substrate supports spaced apart vertically for processes that are capable of being performed in such an arrangement, which can further increase throughput and reduce footprint for such processes.

Furthermore, in some embodiments, the processing tool 100T can be configured to rotate around a central vertical axis, such as around the exhaust inlet 150. In some of these embodiments, the processing tool is configured to rotate at least 90 degrees clockwise and/or counter-clockwise, so that position of the process chambers 101 can be rearranged relative to the transfer robot 170R. When the processing tool 100T can rotate, components for changing the position of the substrates 50 on the transfer robot 170R can be omitted.

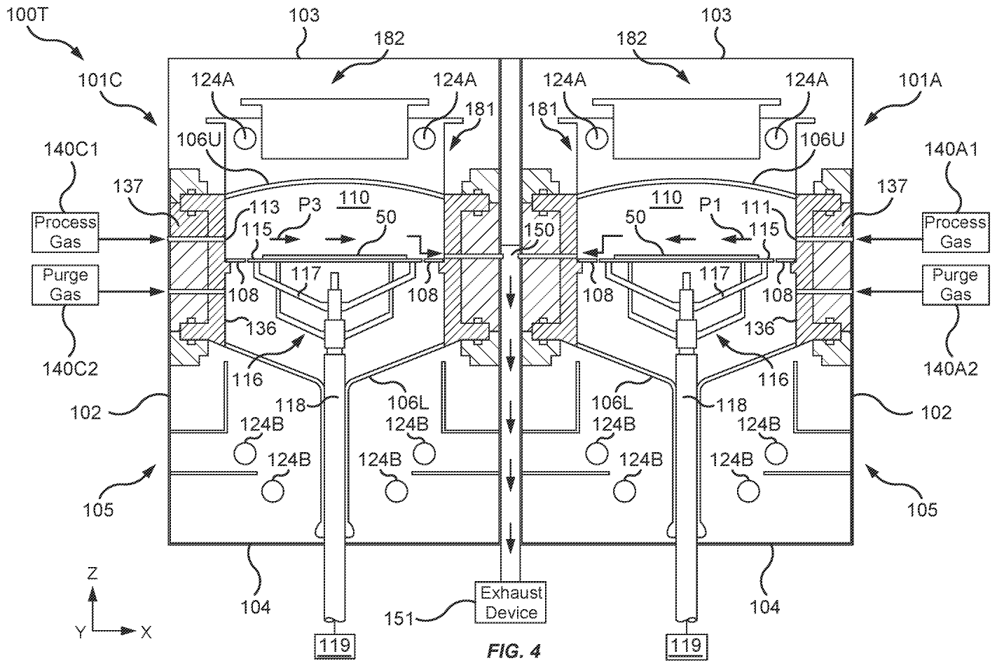

FIG. 4 is a cross-sectional view of the processing tool 100T of FIG. 1 taken along section line 4 of FIG. 3A, according to one embodiment. The processing tool 100T shown in FIG. 4 is an embodiment in which the process chambers 101A, 101C are both epitaxial deposition chambers. In some embodiments, each process chamber 101 of the processing tool 100T can be an epitaxial deposition process chamber. This can be useful, for example, when the processing tool 100T is used to perform alternating depositions, such as a first pair of process chambers 101A, 101B to perform a first deposition (e.g., a silicon nitride deposition) and a second pair of process chambers 101C, 101D to perform a second deposition (e.g., a silicon oxide deposition).

In the embodiment shown in FIG. 4 each process chamber 101A, 101C is identical. In the following description, the process chambers 101A, 101C are referred to as process chamber(s) 101. Each process chamber 101 includes a chamber body 105 that includes a top 103, a bottom 104, and the outer wall 102 connecting the top 103 with the bottom 104. The chamber body 105 can also include the corresponding barriers 121-124 for each process chamber 101.

The chamber body 105 is also disposed around structural components of each process chamber 101, such as an upper window 106U, a lower window 106L, an inner liner 136, and an outer liner 137. The liners 136, 137 can be positioned between the windows 106U, 106L and the chamber body 105 to insulate the windows 106U, 106L from the chamber body 105. The windows 106U, 106L and the liners 136, 137 enclose the interior volume 110 (also referred to as process volume) of each process chamber 101. In one embodiment, the windows 106U, 106L can each be formed of a transparent material, such as quartz.

Each process chamber 101 includes a substrate support assembly 116. The substrate support assembly 116 can include supports 117 and a shaft 118. A susceptor 115 (also referred to as the substrate support 115) can be positioned on the supports 117. The substrate support assembly 116 can further include an actuator 119 to rotate and raise the shaft 118 and the susceptor 115. A substrate 50 can be positioned on the susceptor 115 during processing, such as during an epitaxial deposition. The process chamber 101 can further include a preheat ring 108 that can be positioned around the susceptor 115.

Each process chamber 101 can further include upper lamp modules 124A and lower lamp modules 124B for heating of the substrate 50 and/or the interior volume 110. In one embodiment, the upper lamp modules 124A and the lower lamp modules 124B are infrared (IR) lamps.

Each process chamber 101 further includes an outer reflector 181 and an inner reflector 182. The outer reflector 181 can be positioned around the inner reflector 182. In some embodiments one or more upper lamp modules 124A can be positioned inside the outer reflector 181. The reflectors 181, 182 can assist in achieving temperature uniformity across the substrate during processes, such as during epitaxial depositions.

The first process chamber 101A is connected to two gas source 140A that include a process gas source 140A1 and a purge gas source 140A2. The process gas from the process gas source 140A1 enters the interior volume 110 of the first process chamber 101A at the gas inlet 111 and flows over the substrate 50 and substrate support 115 along the path P1 to the exhaust inlet 150. The third process chamber 101C is connected to two gas source 140C that include a process gas source 140C1 and a purge gas source 140C2. The process gas from the process gas source 140C1 enters the interior volume 110 of the third process chamber 101C at the gas inlet 113 and flows over the substrate 50 and substrate support 115 along the path P3 to the exhaust inlet 150. The purge gas from the purge gas source 140A2, 140C2 can enter the interior volume 110 at a location below the susceptor 115 in each process chamber 101. The purge gas can prevent the process gases from entering the portion of the interior volume 110 in each process chamber 101A, 101C below the susceptor 115. The purge gases and process gases are then exhausted from the interior volumes 110 through the exhaust inlet 150 by the exhaust device 151.

While the foregoing is directed to examples of the present disclosure, other and further examples of the disclosure may be devised without departing from the basic scope thereof, and the scope thereof is determined by the claims that follow.

What is claimed is:

1. A processing tool comprising:
an exhaust inlet;
two or more process chambers surrounding the exhaust inlet, each process chamber comprising:
a chamber body enclosing an interior volume, the chamber body comprising a plurality of sidewalls that include one or more outer walls and one or more inner walls;
one or more substrate supports disposed in the interior volume;
a plurality of lamps positioned over each substrate support;
a window positioned between the plurality of lamps and the substrate support; and
a gas inlet that is located closer to one of the one or more outer walls than the gas inlet is to each of the one or more inner walls.

2. The processing tool of claim 1, wherein the exhaust inlet is located at a central location of the processing tool.

3. The processing tool of claim 1, wherein for each process chamber, the one or more inner walls form a barrier between the interior volume of the process chamber and the interior volume of another one of the two or more process chambers.

4. The processing tool of claim 3, further comprising a first internal port configured to open to form a passageway from the interior volume of a first process chamber of the two or more process chambers to the interior volume of a second process chamber of the two or more process chambers.

5. The processing tool of claim 4, further comprising a second internal port, wherein
the two or more process chambers comprises four or more process chambers, and
the second internal port is configured to open to form a passageway from the interior volume of a third process chamber of the four or more process chambers to the interior volume of a fourth process chamber of the four or more process chambers.

6. The processing tool of claim 1, wherein the two or more process chambers comprises four process chambers and the chamber body of each of the four process chambers includes two inner walls.

7. The processing tool of claim 1, wherein
the two or more process chambers comprises a first process chamber that includes a first substrate support, and
the gas inlet of the first process chamber is on a first side of the first substrate support, and
the exhaust inlet is on an opposing side of the first substrate support.

8. The processing tool of claim 1, wherein
the two or more process chambers comprises a first process chamber and a second process chamber,
the first process chamber is configured to perform a first process on a substrate positioned in the interior volume of the first process chamber,
the second process chamber is configured to perform a second process on a substrate positioned in the interior volume of the second process chamber, and
the first process is different from the second process.

9. The processing tool of claim 8, wherein the first process chamber is unable to perform the second process on a substrate.

10. The processing tool of claim 1, wherein the gas inlet for each process chamber is part of gas supply line that extends through one of the one or more outer walls of the process chamber.

11. A processing system comprising:
a processing tool comprising:
an exhaust inlet;
one or more outer walls and two or more inner walls, the one or more outer walls and the two or more inner walls disposed around two or more interior volumes that are each coupled to the exhaust inlet, wherein the two or more inner walls and the two or more interior volumes surround the exhaust inlet; and
four or more substrate supports, each interior volume including at least one substrate support; and
a transfer chamber coupled to the processing tool, the transfer chamber including a transfer robot that is configured to:
simultaneously remove a plurality of substrates from the processing tool during a first time period, wherein the plurality of substrates are positioned in a first arrangement over the four or more substrate supports when the substrates are positioned on the transfer robot during the first time period,
change a position of the substrates on the transfer robot; and
simultaneously insert each of the substrates into the processing tool during a second time period, wherein
the plurality of substrates are positioned in a second arrangement over the four or more substrate supports when the substrates are positioned on the transfer robot during the second time period, and
each substrate is positioned over a different substrate support during the second time period relative to the first time period.

12. The processing system of claim 11, wherein
the two or more interior volumes comprises a first interior volume and a second interior volume, and
the processing tool further comprises a first internal port configured to open to form a first passageway from the first interior volume to the second interior volume.

13. The processing system of claim 12, wherein the processing tool further comprises a second internal port configured to open to form a second passageway from the first interior volume to the second interior volume.

14. The processing system of claim 13, wherein
the processing tool further comprises a first external port and second external port each configured to open to form a passageway into the first interior volume from outside of the processing tool, and
the transfer robot is configured to extend an end effector through the first external port and the second external port.

15. The processing system of claim 14, wherein the first external port is aligned with the first internal port and the second external port is aligned with the second internal port.

16. The processing system of claim 11, wherein
the two or more interior volumes comprises four interior volumes that are disposed around the exhaust inlet,
each interior volume includes a substrate support, and
the transfer robot is configured to position a substrate over one of the substrate supports in each of the four interior volumes simultaneously.

17. The processing system of claim 11, further comprising a first gas inlet, wherein
the two or more interior volumes comprises a first interior volume,
the first gas inlet is configured to provide gas to the first interior volume,
the four or more substrate supports includes a first substrate support in the first interior volume, and
the first gas inlet is on a first side of the first substrate support, and
the exhaust inlet is on an opposing side of the substrate support.

18. The processing system of claim 17, wherein the gas inlet is part of a gas supply line that extends through one of the one or more outer walls of the process tool.

19. A processing tool comprising:
an exhaust inlet;
four or more process chambers surrounding the exhaust inlet, each process chamber comprising:
a chamber body enclosing an interior volume, the chamber body comprising a plurality of sidewalls that include one or more outer walls and one or more inner walls;
one or more substrate supports disposed in the interior volume, wherein the one or more inner walls of each process chamber form a barrier between the interior volume of the process chamber and the interior volume of another one of the four or more process chambers;
a plurality of lamps positioned over each substrate support; and
a window positioned between the plurality of lamps and the substrate support;
a first internal port configured to open to form a passageway from the interior volume of a first process chamber of the four or more process chambers to the interior volume of a second process chamber of the four or more process chambers; and
a second internal port configured to open to form a passageway from the interior volume of a third process chamber of the four or more process chambers to the interior volume of a fourth process chamber of the four or more process chambers.

20. The processing tool of claim 19, wherein each process chamber of the four or more process chambers is configured to perform a process that the other process chambers of the four or more process chambers are unable to perform.
